(19) United States
(12) Patent Application Publication
(10) Pub. No.: US 2022/0181647 A1
(43) Pub. Date: Jun. 9, 2022

(54) BORON DOPED SYNTHETIC DIAMOND ELECTRODES AND MATERIALS

(71) Applicants: ELEMENT SIX TECHNOLOGIES LIMITED, DIDCOT, OXFORDSHIRE (GB); UNIVERSITY OF WARWICK, COVENTRY, WARWICKSHIRE (GB)

(72) Inventors: GEORGIA WOOD, COVENTRY (GB); TIMOTHY PETER MOLLART, DIDCOT (GB); JULIE VICTORIA MACPHERSON, COVENTRY (GB)

(73) Assignees: ELEMENT SIX TECHNOLOGIES LIMITED, DIDCOT, OXFORDSHIRE (GB); UNIVERSITY OF WARWICK, COVENTRY, WARWICKSHIRE (GB)

(21) Appl. No.: 17/603,337

(22) PCT Filed: Apr. 6, 2020
(86) PCT No.: PCT/EP2020/059788

§ 371 Date: Oct. 12, 2021

(30) Foreign Application Priority Data
Apr. 9, 2019 (GB) 1905045.9

(51) Int. Cl. H01M 4/96; C25B 11/043; G01N 27/30; H01M 4/86; C01B 32/28; B01J 3/06

(52) U.S. Cl. CPC H01M 4/96; C25B 11/043; G01N 27/308; H01M 4/8668; C01B 32/28; B01J 3/065; C01P 2004/03; B01J 2203/068; C01P 2006/40; C01P 2002/54; C01P 2002/82; C01P 2002/60; B01J 2203/0655

(57) ABSTRACT

An electrode comprising synthetic high-pressure high-temperature diamond material, the diamond material comprising a substitutional boron concentration of between 1×10²⁰ and 5×10²¹ atoms/cm³ and a nitrogen concentration of no more than 10¹⁹ atoms/cm³. The electrode has a ΔE_{3/4-1/4} as measured with respect to a saturated calomel reference electrode in an aqueous solution containing 0.1 M KNO₃ and 1 mM of Ru(NH₃)₆³⁺ selected any of less than 70 mV, less than 68 mV, less than 66 mV, and less than 64 mV, and/or a peak to peak separation ΔEₚ as measured with respect to a saturated calomel reference electrode in an aqueous solution containing 0.1 M KNO₃ and 1 mM of Ru(NH₃)₆³⁺ selected any of less than 70 mV, less than 68 mV, less than 66 mV, and less than 64 mV.

### FIELD OF INVENTION

The invention relates to the field of boron doped synthetic diamond electrodes and materials.

### BACKGROUND OF INVENTION

The use of electrically conducting diamond as an electrode material is well established. Such diamond electrodes are very versatile and have a wide range of electrochemical applications which include the selective detection and measurement of both inorganic (e.g. heavy metals and cyanides) and organic compounds (e.g. biosensor applications), wastewater treatment (e.g. reduction of nitrates), and the generation of ozone. The wide applicability of the diamond electrode is due to its unique properties: mechanical strength, chemical inertness, low background interference (high signal to noise ratio) and wide potential window.

Diamond is a wide bandgap semiconductor, with an indirect gap of 5.47 eV, all known dopants for diamond are deep. However when boron concentration in diamond is greater than 1×10²⁰ atoms cm⁻³, the acceptor levels overlap with the valence band as the diamond undergoes the Mott transition to demonstrate metal-like conductivity, in that they obey Ohm's law. Doping below this level results in p-type semi-conducting electrodes. The electronic level of the nitrogen donor is too deep in the band gap to give useful electrical conductivity. Generally, boron doped diamond (BDD) electrodes are made by the chemical vapour deposition (CVD) of BDD onto a suitable substrate, such as a plate or wire. The deposition of boron-doped diamond layers on a substrate by a chemical vapour deposition method (CVD) is taught by, for example, EP0518532 and U.S. Pat. No. 5,635,258. The synthesis of boron-containing diamonds by a high pressure, high temperature (HPHT) solvent/catalyst method is taught by U.S. Pat. No. 4,042,673. For the diamond material to exhibit metal like conductivity, the boron must be substitutionally doped, at high enough density; in other words, it must replace a carbon atom in the diamond crystal lattice rather than be present in interstitial locations or as inclusions.

To illustrate the possible uses of diamond electrodes, U.S. Pat. No. 5,399,247 describes the use of a diamond electrode for the treatment of waste water. WO01/98766 teaches the use of a diamond electrode in the quantitative analysis of xanthin type compounds. WO01/25508 discloses the production of peroxopyrosulphuric acid with a diamond electrode, and U.S. Pat. No. 6,106,692 teaches a method of quantitative analysis of a plurality of target substances using a diamond electrode.

Disadvantages of CVD diamond electrodes include that the CVD production process is energy intensive, time-consuming and the resulting electrodes are therefore expensive. Deposition of CVD diamond is planar and produces a sheet electrode material with a relatively low surface area. For many electrochemical applications, there is a need to be able to provide diamond electrodes with a larger surface area than CVD diamond electrodes without significantly sacrificing the desirable properties of the electrodes such as robustness and inertness. WO03/066930 describes a porous diamond electrode manufactured from a polycrystalline mass of boron-doped diamond produced using a high-pressure high-temperature (HPHT) method. However, diamond electrodes made in this way typically do not display metal-like conductivity, have a narrow solvent window and thus exhibit poor electrochemical reversibility towards appropriate redox couples.

### SUMMARY OF INVENTION

It is an objective to provide an improved high-pressure high-temperature (HPHT) diamond electrode. The inventors have realised that the presence of certain impurities, such as dopants, non-diamond carbon, metals and defects in boron doped diamond material are detrimental to the electrical conductivity via semiconductor mechanisms of the material. For boron doped CVD diamond material, the atmosphere during growth of the diamond material is very carefully controlled. However, for HPHT diamond material, atmospheric gases and contaminants in raw materials can be incorporated into the diamond. Nitrogen is known to reduce the electrical properties of boron doped diamond because, as a deep level, 1.7 eV, n-type dopant, it leads to charge compensation with boron and additional charge scattering sites that reduce the number of available charge carriers and the charge carriers' mobility. Nitrogen is a commonly found impurity in both CVD and HPHT synthetic diamond. However, for CVD synthetic diamond, nitrogen can be carefully controlled in the deposition atmosphere. Boron doped CVD diamond can therefore be prepared with a concentration of nitrogen that is several orders of magnitude lower than the concentration of boron. The very low levels of nitrogen minimise its compensation effect with respect to the boron in the diamond, and so boron doped CVD diamond is typically an effective conductor. For boron doped HPHT diamond, nitrogen levels cannot typically be controlled so tightly and the quantities of nitrogen in the diamond can have a detrimental effect on the electrical properties of boron doped HPHT diamond, often resulting typically in p-type semiconducting electrodes.

The activation level for boron dopants in diamond is 0.37 electron volts (eV) and for metal-like ohmic conductivity, where the measured resistance of a defined volume of the electrode exhibits a linear relationship with current and voltage, boron is required B>1×10²⁰ atoms cm⁻³, the acceptor levels overlap with the valence band as the diamond undergoes the Mott transition to demonstrate metal-like p-type conductivity. At these doping concentrations there is a significant risk of incorporating non-diamond carbon and a higher density of defects. The growth conditions have to be carefully controlled to mitigate these effects.

According to a first aspect, there is provided an electrode comprising synthetic high-pressure high-temperature diamond material, the synthetic high-pressure high-temperature diamond material having a substitutional boron concentration of between 1×10²⁰ and 5×10²¹ atoms/cm³ and a nitrogen concentration of no more than 10¹⁹ atoms/cm³. The electrode has any of the following characteristics:
a ΔE_{3/4-1/4} as measured with respect to a saturated calomel reference electrode in an aqueous solution containing 0.1 M KNO₃ and 1 mM of Ru(NH₃)₆³⁺ selected any of less than 70 mV, less than 68 mV, less than 66 mV, and less than 64 mV (this typically is when the electrode is in the form of a microelectrode); and
a peak to peak separation ΔEₚ as measured with respect to a saturated calomel reference electrode in an aqueous solution containing 0.1 M KNO₃ and 1 mM of Ru(NH₃)₆³⁺ selected any of less than 70 mV, less than 68 mV, less than 66 mV, and less than 64 mV (this typically is when the electrode is in the form of a microelectrode). This provides an electrode that has a sufficiently high concentration of substitutional boron to act as an electrical conductor, and a sufficiently low concentration of incorporated nitrogen such that the compensation effect of nitrogen is minimised.

As an option, an sp² carbon content of the electrode is sufficiently low as to not exhibit non-diamond carbon peaks in a Raman spectrum of the electrode.

The synthetic high-pressure high-temperature diamond material optionally has a boron content selected from any one of at least 2×10²⁰ boron atoms cm⁻³, at least 3×10²⁰ boron atoms cm⁻³, at least 5×10²⁰ boron atoms cm⁻³, and at least 7×10²⁰ boron atoms cm⁻³.

In an optional embodiment, the electrode comprises inter-grown grains of the synthetic high-pressure high-temperature diamond material.

In an alternative optional embodiment, the electrode comprises particles of the synthetic high-pressure high-temperature diamond material dispersed in or on an electrically non-conductive matrix material. The non-conductive matrix material is optionally selected from any of a polymer, Nafion, insulating oil, and an insulating ink.

In an alternative optional embodiment, the electrode comprises particles of the synthetic high-pressure high-temperature diamond material dispersed in or on a conductive matrix material. The conductive matrix material is optionally selected from any of a conducting polymer, a non-diamond carbon support, and conducting ink.

In an alternative optional embodiment, the electrode comprises a container containing particles of the synthetic high-pressure high-temperature diamond material, the container having at least one opening through which, in use, an electrolyte can pass. As a further option, the container comprises at least one wall, the wall having porosity through which, in use, the electrolyte can pass.

In an alternative optional embodiment, the electrode comprises a compacted body of particles of the synthetic high-pressure high-temperature diamond material. As a further option, the particles of synthetic diamond material have an average grain size selected from any of a range of 5 nm to 500 μm, 10 nm to 200 μm, 50 nm to 100 μm, and 100 nm to 10 μm.

According to a second aspect, there is provided a method of making an electrode comprising synthetic high-pressure high-temperature diamond material, the method comprising:
providing synthetic high-pressure high-temperature diamond material, the synthetic high-pressure high-temperature diamond material having a substitutional boron concentration of between 1×10²⁰ and 5×10²¹ atoms/cm³ and a nitrogen concentration of no more than 10¹⁹ atoms/cm³; and
forming the synthetic high-pressure high-temperature diamond material into an electrode.

The step of forming the synthetic high-pressure high-temperature diamond material into an electrode optionally comprises providing a reaction mass comprising high-pressure high-temperature diamond material and a catalyst material, subjecting the reaction mass to a temperature greater than 1300° C. and a pressure of greater than 4.0 GPa to form an body comprising inter-grown grains of diamond material, and removing catalyst material from the body to form the electrode. The catalyst material is optionally selected from any of iron, nickel, cobalt, manganese, and alloys thereof, and the step of removing catalyst material from the body comprises leaching the body in acid.

As an alternative option, the step of forming the synthetic high-pressure high-temperature diamond material into an electrode comprises dispersing particles of the high-pressure high-temperature diamond material in or on a non-conductive matrix material. The non-conductive matrix material is optionally selected from any of a polymer, Nafion, insulating oil, and an insulating ink.

As an alternative option, the step of forming the synthetic high-pressure high-temperature diamond material into an electrode comprises dispersing particles of the synthetic high-pressure high-temperature diamond material in or on a conductive matrix material. The conductive matrix material is optionally selected from any of a conducting polymer, a non-diamond carbon support, and conducting ink.

As an alternative option, the step of forming the synthetic high-pressure high-temperature diamond material into an electrode comprises providing a container having at least one opening and locating particles of the synthetic high-pressure high-temperature diamond material in the container.

As an alternative option, the step of forming the synthetic high-pressure high-temperature diamond material into an electrode comprises compacting a plurality of particles of the synthetic high-pressure high-temperature diamond material at a pressure of at least 4.5 GPa and a temperature of at least 1400° C. to form a compacted body.

According to a third aspect, there is provided a particle of synthetic high-pressure high-temperature diamond material comprising:
a substitutional boron concentration of between 1×10²⁰ and 5×10²¹ atoms/cm³; and
a nitrogen concentration of no more than 10¹⁹ atoms/cm³; and
the particle of synthetic high-pressure high-temperature diamond material having any of the following characteristics:
   a ΔE_{3/4-1/4} as measured with respect to a saturated calomel reference electrode in an aqueous solution containing 0.1 M KNO₃ and 1 mM of Ru(NH₃)₆³⁺ selected any of less than 70 mV, less than 68 mV, less than 66 mV, and less than 64 mV; and
   a peak to peak separation ΔEₚ as measured with respect to a saturated calomel reference electrode in an aqueous solution containing 0.1 M KNO₃ and 1 mM of Ru(NH₃)₆³⁺ selected any of less than 70 mV, less than 68 mV, less than 66 mV, and less than 64 mV.

As an option, the particle of synthetic high-pressure high-temperature diamond material had a substitutional boron content selected from any one of at least 2×10²⁰ boron atoms cm⁻³, at least 3×10²⁰ boron atoms cm⁻³, at least 5×10²⁰ boron atoms cm⁻³, and at least 7×10²⁰ boron atoms cm⁻³.

The particle of synthetic high-pressure high-temperature diamond material optionally has a largest linear dimension selected from any of a range of 5 nm to 500 μm, 10 nm to 200 μm, 50 nm to 100 μm, and 100 nm to 10 μm.

### BRIEF DESCRIPTION OF THE DRAWINGS

For a better understanding of the present invention and to show how the same may be carried into effect, embodiments of the present invention will now be described by way of example only with reference to the accompanying drawings, in which:

FIG. 1 is a flow diagram showing exemplary steps for production of HPHT BDD grit and production of compacted BDD disc;

FIG. 2 is a bar chart showing exemplary size distribution of resultant HPHT BDD grit particles;

FIG. 3 is a series of FE-SEM images showing morphology (a and d), surface defects (b and e), and compact surface structure (c and f) of HPHT BDD particles made with 3.6 wt % AlB₂ (a-c) and 4.8 wt % AlB₂ (d-f);

FIG. 4 shows Raman spectra of a) intrinsic diamond and HPHT BDD compacts with a) 3.6 wt % AlB₂ and b) 4.8 wt % AlB₂;

FIG. 5 shows cyclic voltammograms CVs recorded in 0.1 M KNO₃ at a scan rate of 0.1 V s⁻¹ of HPHT BDD compacts with 3.6 wt % AlB₂ and b) 4.8 wt % AlB₂;

FIG. 6 shows cyclic voltammograms in 1 mM Ru(NH₃)₆^{3+/2+} and 0.1 M KNO₃ at 0.1 V s⁻¹ of a 4.8% AlB₂ HPHT BDD compact before and after coating with poly(oxyphenylene), and after polishing of the coating;

FIG. 7a is an EBSD image of the SECCM scan area on the 4.8 wt % AlB₂ HPHT BDD compact, and FIGS. 7b to 7d are cyclic voltammograms recorded in 10 mM Ru(NH₃)₆Cl₃ and 0.01 M KNO₃ at 10 V s⁻¹ on 001, 101, and 111 facets;

FIG. 8a illustrates schematically a structure of apparatus, herein referred to as a single particle electrode (SPE), for interrogating the electrochemical behaviour of a single BDD particle;

FIGS. 8b to 8d show cyclic voltammograms recorded in 0.1 M KNO₃ at a scan rate of 0.1 V s⁻¹ of the HPHT BDD SPE to show b) the solvent window, c) a typical capacitance curve recorded, and the electrode response in d) CVs recorded in 1 mM Ru(NH₃)₆^{3+/2+} and 0.1 M KNO₃ at scan rates of 0.1, 0.05, 0.02, and 0.005 V s⁻¹ for a HPHT BDD (4.8 wt % AlB₂ additive) SPE;

FIG. 9 shows an FE-SEM image of the top surface of a silicon carbide polished HPHT BDD SPE shown in FIG. 7a.

### DETAILED DESCRIPTION

The inventors have realised that a significant problem with boron doped diamond grit made using a high pressure high temperature (HPHT) route is that the atmosphere during an HPHT process is typically not controlled. This allows atmospheric nitrogen to be incorporated into the crystal lattice in quantities that can disrupt the electrical properties of the substitutionally incorporated boron in the crystal lattice. This means that an HPHT boron doped diamond material may not have the same electrical properties as a CVD boron doped diamond material with the same levels of boron doping, if unwanted nitrogen doping in the HPHT diamond is sufficiently high.

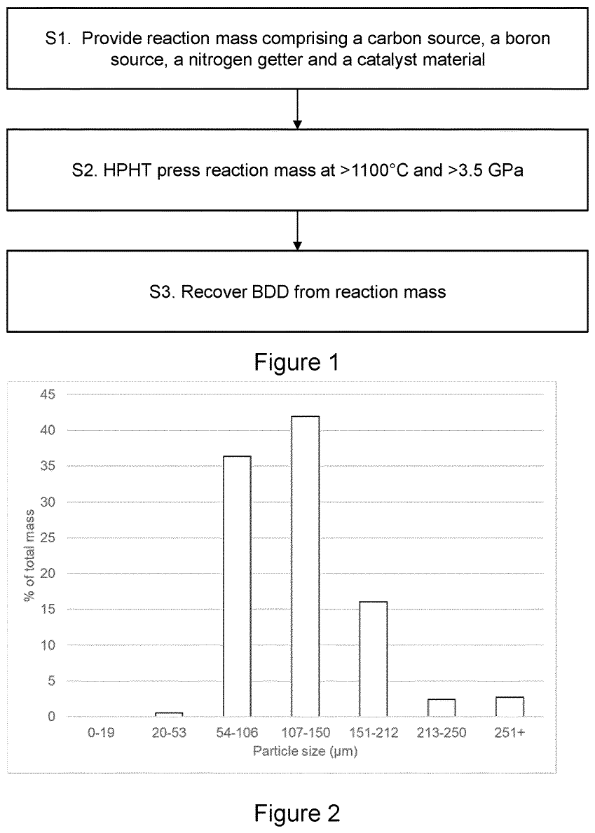

Boron doped diamond (BDD) grits were prepared using the high-pressure high temperature (HPHT) process. The process is summarised in FIG. 1, with the following numbering corresponding to that of FIG. 1.

S1. A reaction mass comprising a carbon source, a catalyst material, a source of a nitrogen getter material and a source of boron is prepared. In some cases it may be desirable to also add diamond seeds to the reaction mass. An exemplary carbon source is graphite powder. Exemplary catalyst materials are transition metal particles, typically selected from any of iron, nickel, cobalt, manganese and alloys or mixtures thereof. During a subsequent HPHT operation the catalyst forms a solvent in which carbon can dissolve. Exemplary sources of boron include amorphous boron and aluminium diboride. Exemplary sources of nitrogen getter material include aluminium powders titanium powders and aluminium diboride. Note that aluminium diboride can act simultaneously as both a source of boron and a source of nitrogen getter material.

S2. The reaction mass is pressed in an HPHT press at a temperature of at least 1100° C. and a pressure of at least 3.5 GPa. During the pressing the carbon source dissolves in the catalyst material and precipitates as diamond. Most of the boron from the boron source is substitutionally incorporated into the diamond crystal lattice, although some may be incorporated in other forms.

Note that prior to pressing, steps may be taken to reduce the presence of gaseous N2 in the reaction mass by pre-treatment. This may be done in a vacuum and/or using a heat treatment and sealing the reaction mass in a container prior to pressing the reaction mass in the HPHT press. Other steps may be taken to reduce the presence of nitrogen in the reaction mass, such as choosing raw materials that have a low concentration of nitrogen. However, it is important to add the nitrogen getter material to ensure that the nitrogen in the final boron doped diamond is sufficiently low.

The nitrogen getter material is any material that, during step S2, reacts with nitrogen in the reaction mass to form a compound that is thermodynamically stable in the reaction mass and so will not easily incorporate into the diamond lattice as nitrogen that can electrically compensate for substitutional boron. For example, where a source of aluminium such as elemental aluminium is used, the aluminium will react with nitrogen in the reaction mass to form aluminium nitride. Aluminium nitride is thermodynamically stable at the pressing temperature and pressure. This effectively removes the nitrogen from the system and prevents it from being incorporated into the diamond crystal lattice as nitrogen that can electrically compensate for substitutional boron. Similarly, where a source of aluminium such as aluminium diboride is used, the aluminium and boron dissociate allowing the aluminium to react with nitrogen in the reaction mass in the same way as described above.

S3. The reaction mass is removed from the HPHT press and the resultant boron-doped diamond (BDD) is recovered from the reaction mass. This may be done, for example, by one or more acid treatments as is known to the skilled person.

The resultant boron doped diamond material has much lower levels of nitrogen incorporation than boron doped diamond material made without a nitrogen getter in the reaction mass, and so has greater electrical conductivity due the lesser degree of charge compensation than boron doped diamond material made without a nitrogen getter in the reaction mass.

The BDD particles may further be used to make compacts or other structures that can be used as electrodes.

A first exemplary way to form a BDD electrode from the particles is to sinter the particles with a solvent/catalyst material at high pressure and high temperature to form polycrystalline diamond comprising intergrown BDD grains. Acid leaching can be used to remove any remaining catalyst material from the interstices between the grains. The particles may be ground first to a smaller particle size. This would typically leave many of the particles with cleavage fracture surfaces.

A typical HPHT regime is to simultaneously subject a reaction mass of the BDD particles and the catalyst material using temperatures in a range of 1100° C. to 2200° C. and pressures of 3.5 GPa to 8 GPa. Catalyst materials are typically selected from iron, cobalt, nickel, manganese, and alloys or mixtures thereof. An advantage of electrodes made in this way is that they are extremely dense.

A second exemplary way to form a BDD electrode from the particles is to disperse the particles in or on a conducting matrix material, such as a conducting polymer/ink or carbon support. In this way intimate electrical contact between particles is not necessarily required.

A third exemplary way to form a BDD electrode from the particles is to disperse the particles in or on a non-electrically conducting matrix, such as Nafion, mineral oil, insulating polymer or plastic. The particles may or may not be in intimate contact. For the latter, the particles could be electrochemically interrogated via a bipolar arrangement or by placement on a second conductive support. For example, Nantaphol et. al. Anal. Chem., 2017, 89 (7), pp 4100-4107 describe the use of a paste that includes boron doped diamond for microfluidic paper-based analytical devices. Kondo et. al. J. Electrochem. Soc., 165 (6) F3072-F3077 (2018) describe boron-doped diamond powder used as a support for Pt-based cathode catalysts in polymer electrolyte fuel cells.

A fourth exemplary way to form a BDD electrode is to locate the particles in a container. The container has an inlet and outlet, or porous walls, to allow electrolyte to flow through the container. The container in used is placed in the electrolyte and acts as an electrode. In use, the electrolyte can pass through the inlet and outlet (or porous walls) and interact with the BDD diamond particles.

A fifth exemplary way to form a BDD electrode is to form a compact from the particles. A plurality of particles is pressed together without any solvent or catalyst material at pressures of 4 to 8 GPa and a temperature of at least 1400° C. In this instance at least 95% of the compacted particles are in electrical contact with one another; in other words, when a voltage is applied across one particle, the voltage across all particles in electrical contact with one another is raised.

The invention will now be described by way of examples. In a first example, 10 g of a reaction mass was prepared containing 5 g of graphite powder (50 wt %), 3.5 g of iron powder (35 wt %), 1.5 g of nickel powder (15 wt %), and 0.002 g of diamond seed. A single steel ball (10 mm diameter) was added to the reaction mass and the pot mixed for 30 minutes with a turbulent mixer. 1 kg batches of undoped powder were then prepared containing 500 g of graphite (50 wt %), 350 g of iron (35 wt %), 150 g of nickel (15 wt %), and 1.525 g of the reaction mass (0.305 mg of diamond seed per kg). 200 g of steel balls (10 mm diameter) were added (1:5 mass ratio of steel balls to powder) and mixed for 3 hours using a cone blender. The undoped powder was then mixed with aluminium diboride (AlB₂: the source of the boron) to produce a powder mix containing two different concentrations of AlB₂, as shown in Table 1. Again, steel balls (10 mm diameter, 1:5 ball to powder ratio) were added to these powders which were then mixed for 1 hour using a cone blender. The boron containing powder mixtures were sieved to remove the balls and then compacted into cylinders (18 g per slug) and heated to 1050° C. under vacuum to remove oxygen and hydrogen impurities. HPHT synthesis was carried out at around 5.5 GPa and 1200° C. in a cubic anvil HPHT apparatus.

TABLE 1
Composition of boron-containing powder mixes

| AlB₂ (wt %) | AlB₂ (g) | Undoped powder mix (g) | Total mass (g) |
|---|---|---|---|
| 3.6 | 19.8 | 530.2 | 550 |
| 4.8 | 26.4 | 523.6 | 550 |

The BDD particles were recovered from the reaction mass and purified by a series of acid treatments. Slugs were first crushed into small pieces using a Weber press to apply a force of 100 kN. For the following cleaning procedure, two slugs were recovered simultaneously in the same reaction vessel. First, the crushed pieces were heated at 250° C. in HCl (2.0 L) for 22 hours. When cool, the solution was decanted through an 80 μm sieve and the acid discarded. The remaining solids were then subjected to three rinses with deionised water. Next, the BDD was boiled at 250° C. in a 3:1 mix of H₂SO₄ and HNO₃ (1.5 L and 0.5 L, respectively) for 22 hours. Again, the solution was decanted through an 80 μm sieve, the acid discarded, and the remaining solids rinsed three times with deionised water. H₂SO₄ (0.5 L) was then added to the BDD and heated to 300° C. Once boiling, approximately 10 g of KNOB crystals were added and the solution left for an additional 30 minutes. Once cool, the solution was sieved and washed as previously. Finally, the BDD particles were added to 100 mL of deionised water in a beaker and placed in an ultrasonic bath for 20 minutes to remove any residual graphite. After this time, the waste water was carefully decanted, and the process repeated until the water remained colourless after ultrasonication. This water was then also decanted and the BDD particles left to dry overnight in a 60° C. oven.

FIG. 2 is a bar chart showing exemplary size distribution of resultant HPHT BDD grit particles measured by sieving. It can be seen that most of the particles were in the range of 54 to 212 μm. However, the skilled person will appreciate that the average particle size can be affected by the time, temperature and pressure of the HPHT processing. Furthermore, it will be appreciated that the particles could be ground or crushed to reduce the average particle size.

To produce HPHT BDD compacts, approximately 2 g of BDD particles were compacted at around 6.6 GPa and 1700° C. in a cubic anvil HPHT apparatus to produce hot compacted solid BDD discs. Each compact was treated for 24 hours in a mixture of 50 mL HF and 50 mL HNO₃ to release the compacts from the capsule residue. A final degraphitisation treatment was applied by annealing for 5 hours at 450° C. in air, before polishing one side of each compact to leave a smooth surface for characterisation. The circular compacts produced had a diameter of approximately 16 mm and a thickness of 2 mm. To carry out electrochemical characterisation, a titanium (Ti: 10 nm)/gold (Au: 400 nm) contact was sputtered (Moorfield MiniLab 060 Platform Sputter system) onto the rough side of each compact and annealed in air (400° C. for 5 hours) to create an Ohmic contact. Each compact was then placed upon a Ti/Au coated glass slide with CircuitWorks conductive silver epoxy (Chemtronics) in contact with both the slide and the Ti/Au contact and left to dry in a 60° C. oven for at least one hour.

Electrodes were also fabricated from single BDD particles (4.8 wt % AlB₂ only). Metal contacts were sputtered onto one end of an individual BDD particle and then annealed as described above. Conductive silver epoxy was used to adhere individual particles to lengths of PVC insulated copper wire which had been polished with silicon carbide pads to a point. These were left to dry in a 60° C. oven for at least one hour. These assemblies were then sealed using epoxy resin (Epoxy Resin RX771C/NC, Aradur Hardener HY1300 GB, Robnor Resins), and dried at room temperature for 72 hours. After drying, excess epoxy was removed by carefully polishing with silicon carbide pads of decreasing roughness until the BDD particle was exposed to produce a single particle electrode (SPE).

The BDD particles and electrodes were characterised in the following ways:

Raman Spectroscopy measurements were performed using Renishaw inVia Reflex Raman microscope with a 532 nm (2.33 eV) solid state laser and a laser power of 3.6 mW.

Field emission scanning electron microscopy (FE-SEM) images of the BDD particles and compact were taken using a Zeiss Gemini 500.

The nitrogen content of the particles was determined by inert gas fusion infrared and thermal conductivity detection using an ON736 Oxygen/Nitrogen Elemental Analyzer (LECO Corporation).

Glow discharge mass spectrometry (GDMS) was utilised to characterise the boron content of the HPHT BDD particles.

Secondary ion mass spectrometry (SIMS) was used to characterise the boron content of the compact disks. Note that the boron concentration value obtained using SIMS can be variable according to how the SIMS measurements are performed and calibrated. SIMS may be calibrated by assuming the proportion of the boron signal is a linear function of the carbon signal in the diamond over the concentration range 1×10¹⁴ atoms cm⁻³ to 7×10²¹ atoms cm⁻³. A calibration standard was prepared by ion implantation of boron into a single crystal diamond sample with a peak boron concentration of 1×10¹⁹ atoms cm⁻² at a depth of 1 μm. A SIMS profile versus sample depth is used to generate the linear calibration factor for the given experimental conditions.

Note that GDMS and SIMS give information about the total boron content, which includes free and compensated boron. These are not necessarily an indication of how good the electrical properties of the diamond are. Raman measurements, on the other hand, only shows electrically active boron in the diamond.

Electrical properties (including solvent window, capacitance, and response to redox couples) were determined by cyclic voltammetry measurements. These are described in detail in WO 2013/135783. For boron doped diamond materials, a low boron dopant content (below the metallic threshold) can aid in providing a large solvent window, flat electrochemical response, and low capacitance. However, such material will not show metallic like electrochemical properties resulting in non-reversible electrochemical characteristics for simple fast electron transfer outer sphere redox couples in the both positive and negative potential windows and is thus not desirable for electrochemical sensing applications. Increasing the boron dopant content significantly to metallic conduction levels will cause the solvent window to shrink and the capacitance to increase slightly. As such, it is thought that an optimum range of boron concentration exists which balances the requirement of reversible electrochemistry for simple fast electron transfer outer sphere redox couples versus the desirable characteristics of a large solvent window, a flat electrochemical response, and a low capacitance. Furthermore, the addition of too much boron tends to increase the amount of defects in the BDD, which negatively affects the electrical conduction properties.

In addition to the above, it has been found that sp² carbon content within the boron doped diamond material or electrode is undesirable, as this also shrinks the solvent window, due to the electrocatalytic effects of the sp² carbon, increases capacitance, and may make the material appear more electrically conducting than it actually is. If the boron dopant content becomes too high then it is more difficult to control the presence of non-diamond carbon, e.g. sp² carbon, providing an additive detrimental effect on the performance of the electrode material in terms of providing a wide, flat baseline for species detection.

Cyclic voltammetry was carried out using a CH Instruments potentiostat (600B, 760E or 800B). A three-electrode droplet cell setup was used with a compact BDD or BDD SPE as working electrode, platinum coil counter electrode and either a saturated calomel reference electrode (SCE) or Ag/AgCl electrode as reference. All potentials are quoted with respect to the reference electrode. Each measurement was recorded for a 1 mm diameter circular area of the surface exposed, achieved by using a piece of Kapton tape with a 1 mm diameter circular, laser cut hole, exposed. Before measurements were taken, the surface of each BDD compact was electrochemically cleaned by running cyclic voltammograms (CVs) between −2.0 V and +0.2 V in 0.1 M H₂SO₄.

Solvent window and capacitance measurements were run in 0.1 M KNO₃ at a scan rate of 0.1 V s⁻¹. Electrode response to the fast electron transfer outer sphere redox couple Ru(NH₃)₆^{3+/2+} was also investigated by recording CVs in the presence of 1 mM and 10 mM Ru(NH₃)₆ Cl₃ in 0.1 M KNO₃ at scan rates in the range 0.005 V s⁻¹ to 0.1 V s⁻¹. After every scan, the surface of the BDD compact or BDD SPE, Pt counter electrode, and Ag/AgCl reference electrode were rinsed with deionised water.

In order to investigate material porosity, the polished surface of a HPHT BDD compact was coated with a thin, uniform, pinhole free, insulating film of poly(oxyphenylene). This was achieved by the electropolymerisation of a freshly made solution containing 60 mM phenol, 90 mM 2-allyphenol, and 160 mM 2-n-butoxyethanol in water/methanol (1:1 by volume). The pH of the monomer solution was adjusted by the addition of ammonium hydroxide, dropwise, until a pH of 9.2 was reached. A voltage of +2.5 V against a silver wire quasi-reference electrode was applied for 20 minutes. After deposition, the surface was rinsed in 1:1 water/methanol, and the copolymer film heat cured for 30 minutes at 150° C. To remove the polymer coating, the HPHT BDD compact surface was polished using alumina micropolish (0.05 μm, Buehler) with a cotton bud, before rinsing with distilled water. Electrochemical characterisation data was recorded following the procedure described above and after deposition of the insulating polymer film, and after the polymer coating had been removed by polishing.

For scanning electrochemical cell microscopy (SECCM) measurements, nanopipettes were pulled from borosilicate glass single barrel capillaries (1 mm outer diameter, 0.5 mm inner diameter, Harvard Apparatus) using a Sutter P-2000 laser puller (Sutter Instruments, USA). After pulling, the inner diameters of the end of the nanopipettes were in the range of 1 μm. The outer walls were silanised by dipping the nanopipette in dichlorodimethylsilane (>99% purity, Acros) whilst flowing argon through to ensure the inside walls are not silanised. This treatment minimises solution spreading from the pipet to the sample surface.

The nanopipette was filled with solution containing 10 mM Ru(NH₃)₆Cl₃ and 0.01 M KNOB and an Ag/AgCl quasi-reference-counter electrode (QRCE) inserted into the back of the nanopipette. A hopping mode was employed (spatial resolution or ‘hopping distance’ of 5 μm) and the nanopipette used to make a series of voltammetric measurements at each pixel across a 200×200 μm area of the HPHT BDD compact (4.8 wt % AlB₂ only) surface (working electrode). The potential applied to the QRCE was swept from +1 V to −1 V, then back to +1 V at a scan rate of 10 V s⁻¹, and the current at the surface was recorded. All data analysis was performed using Matlab (R2014b, Mathworks). The crystal orientation of the compact surface for the SECCM scanned area was determined by electron backscatter diffraction (EBSD).

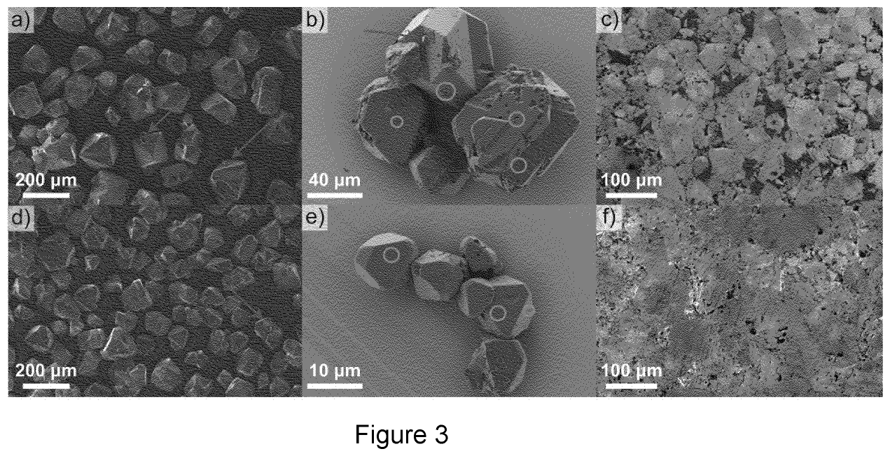

Field emission scanning electron microscopy (FE-SEM) was employed to investigate the morphology and size of the BDD particles produced after HPHT growth under two different boron doping conditions. FIG. 3 shows FE-SEM images. FIGS. 3a and 3d show powder morphology, FIGS. 3b and 3e show surface defects of individual particles, and FIGS. 2c and 2f show the structure of compacts. FIGS. 3a to 3c are HPHT BDD particles made with 3.6 wt % AlB₂, and FIGS. 3d to 3f are HPHT particles made with 4.8 wt % AlB₂. Arrows indicate surface nucleation and Circles indicate holes found on particle surfaces.

The presence of crystallographic defects including surface nucleation (indicated with arrows, FIGS. 2a, b, and c), where small crystallites nucleate and grow on the faces of larger crystals, small holes found on some crystal faces (particularly the predominant {111} faces, indicated with green circles, FIGS. 2b and e), and general deformation from perfect crystallinity, particularly at the corners of individual crystals (FIG. 2b), observed are typical of highly doped BDD. Surface nucleation occurs as a result of the increasing number of defect sites on the growing BDD surfaces as added boron disrupts the diamond lattice. On the {111} face, each carbon atom is bonded to three carbon atoms with one dangling bond through which the lattice is extended. When a boron atom sits in place of a carbon atom on the {111} face, there is no dangling bond as it only has three valence electrons. Additional carbon atoms cannot bond to the boron sites on the {111} face as the crystal grows, leaving bald-points on the surface. Conversely, when boron substitutes carbon on the {100} face, one boron atoms bonds to two carbon atoms and thus one dangling bond is left to extend the lattice. This also decreases the growth rate along the <111> direction which in turn explains why {111} faces predominate at high boron concentrations, as in crystal growth the fastest growing faces (in this case {100}) grow out leaving the slow faces to dominate.

The surfaces of the particles are thought to be free from residual metallic impurities which have been successfully removed during processing. It is important to note that Fe and Ni may still be present in small quantities as inclusions contained entirely within BDD particles, however this will not affect electrochemical properties as electrochemical process occur only at the interface between surface and solution.

FE-SEM images were also taken of the polished surface of the BDD compacts (FIGS. 3c and f). The presence of much smaller BDD particles known as fines is observed for both compacts which are produced during the compaction and fill some of the small gaps where the BDD crystals are pushed together. Also observed are some small cracks and voids where particles meet which suggest that this material is likely to have a porosity associated with it, as no binder is present during the compact to completely fill these gaps. A greater extent of connection between particles, with fewer and smaller holes between them, was observed for the 4.8 wt % AlB₂ additive sample (FIG. 2f) compared to 3.6 wt % AlB₂ (FIG. 2c) where BDD particles appear more isolated and distinct.

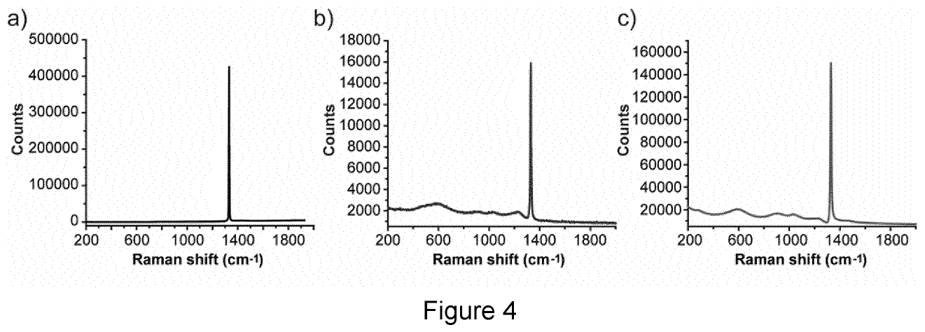

As shown in FIG. 4, Raman measurements were taken of the two differently boron doped compacts and compared to a spectrum obtained for undoped diamond. FIG. 4a shows a Raman spectrum for undoped diamond, FIG. 4b shows a Raman spectrum for HPHT diamond prepared using 3.6 wt % AlB₂ and FIG. 4c shows a Raman spectrum for HPHT diamond prepared using 4.8 wt % AlB₂.

The presence of boron in the diamond lattice is confirmed by the presence of peaks at ˜550 cm⁻¹ and ˜1200 cm⁻¹, a signature of highly doped BDD and not observed in the undoped sample. The 550 cm⁻¹ peak is thought to be attributed to local vibration modes of boron pairs within the lattice. The broad 1200 cm⁻¹ band corresponds to a maximum in the phonon density of states which arises from the disorder introduced by boron doping. The diamond Raman line is also red-shifted slightly relative to the intrinsic diamond line (1332.5 cm⁻¹; as shown in FIG. 4a), occurring at 1330.83 cm⁻¹ and 1329.15 cm⁻¹ for 3.6 wt % AlB₂ and 4.8 wt % AlB₂, respectively, as shown in FIGS. 4b and 4c. This shift is due to boron impurity scattering which cause a tensile residual stress. The larger magnitude shift is observed for the 4.8 wt % AlB₂ samples, suggestive of a higher level of boron doping than for the 3.6 wt % AlB₂ samples. A slight asymmetry of this peak is also observed due to a Fano resonance. The Fano effect occurs due to quantum mechanical interference between the Raman phonon discrete state transition and the energy continuum inter-sub band transitions which are a result of the Fermi level moving into the conduction band due to a high level of boron doping. No graphite peaks are present (the G and D peaks lie at around 1560 cm⁻¹ and 1360 cm⁻¹ respectively), suggesting a lack of sp² carbon impurities either introduced during growth or post processing of the material. The Raman spectra for the HPHT BDD particles used to make the compacts was also obtained, and the same key features observed.

SIMS and GDMS analysis of the boron dopes particles provides the boron dopant levels for the two materials. Whilst both contain greater than 10²⁰ B atoms cm⁻³, and the boron concentration is shown to increase as the amount of AlB₂ added increases, it is only the 4.8% material that also shows an accompanying Fano resonance in the Raman, which is a signature of metal-like doping. The nitrogen content was found to be two orders of magnitude lower than the boron content (Tab. 2), which is vital as nitrogen atoms compensate for boron atoms in the lattice, rendering them electrically inactive

The concentration of boron in the BDD does not vary linearly with the proportion of AlB₂ in the reaction mass. A significant increase in AlB₂ additive leads to only a small increase in substitutional boron concentration results. This suggests that not all of the boron provided from the AlB₂ boron source added to the reaction mass is incorporated into the growing diamond lattice.

TABLE 2
Boron concentration obtained by GDMS
and SIMS and nitrogen concentration

| AlB₂ | [B] from GDMS | [B] from SIMS | [N] |
|---|---|---|---|
| (wt %) | (atoms cm⁻³) | (atoms cm⁻³) | (atoms cm⁻³) |
| 3.6 | 1.96 × 10²⁰ | 1.267 ± 0.008 × 10²⁰ | 7.72 ± 0.35 × 10¹⁸ |
| 4.8 | 2.94 × 10²⁰ | 1.939 ± 0.013 × 10²⁰ | 4.24 ± 0.14 × 10¹⁸ |

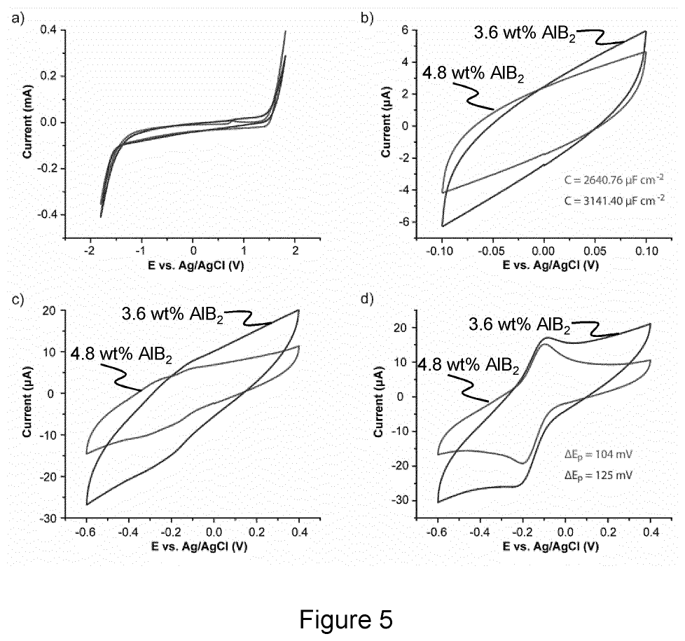

Electrochemical characterisation was carried out on the polished surface of the two differently doped BDD compacts. FIG. 5 shows cyclic voltammograms recorded in 0.1 M KNO₃ at a scan rate of 0.1 V s⁻¹ of HPHT BDD compacts with 3.6 wt % AlB₂ and b) 4.8 wt % AlB₂. The solvent windows obtained in FIG. 5a were wide, however a capacitive component, C, is evident. To calculate C the voltage window is decreased to 0 V±0.1 V and equation 1 is used:

$$C = \frac{{i}_{a ν}}{v A} \qquad ( 1 )$$

where iₐᵥ is the average current at 0 V from the forward and reverse sweep, v is the scan rate (here 0.1 V s⁻¹) and A is the geometric electrode area. For polished CVD-grown BDD a capacitance of ˜6-10 μF cm⁻² is typically reported.³⁶ Here C values of almost three orders of magnitude higher, 3.14 mF cm⁻² and 2.64 mF cm⁻² for 3.6 wt % AlB₂ and 4.8 wt % AlB₂, are obtained, respectively. Given geometric area has been used, the data strongly suggests that there is large accessible surface area due to the porosity of the compact, rather than significant graphitic contributions. To avoid electrochemical interference issues, no binder was added during compaction, so remaining voids between BDD particles are left unfilled. However, for some applications, e.g. super-capacitors, high capacitance materials are desired. Porous electrodes also play a fundamental role in electrochemical fuel cell technology.

To provide information on the electrochemical performance properties of the material, Ru(NH₃)₆³⁺ was employed, due its outer sphere nature and fast electron transfer kinetics. Under typical CV scan conditions on CVD grown BDD, the Ru(NH₃)₆³⁺ response appears very close to reversible (diffusion-controlled), less than 70 mV peak to peak separation, ΔEₚ. Due to very large background currents, however the oxidative and reductive peaks for 1 mM Ru(NH₃)₆³⁺ redox electrochemistry are not truly discernible (FIG. 5a) over the background. Increasing the concentration of Ru(NH₃)₆³⁺ tenfold (FIG. 5d), improves the situation leading to ΔEₚ values of 125 mV and 104 mV for 3.6 wt % AlB₂ and 4.8 wt % AlB₂, respectively. The larger ΔEₚ values could be symptomatic of a non-negligible material resistance leading to Ohmic loss (iR) or less boron than expected in the diamond. As the Raman spectra obtained for both 3.6 wt % and 4.8 wt % AlB₂ compacts (shown in FIG. 4) indicate high boron doping, the effect of particle to particle contact resistances in the compact material is likely to be the most significant factor. Boron content may still play a role though, as indicated by the lack of a Fano resonance for the 3.6 wt % AlB₂ compact, and also may explain why a lower capacitance and peak-to-peak separation are observed for the 4.8 wt % AlB₂ compact. However, compact porosity also makes analysis of the data challenging, as quantitative interpretation of peak to peak separations is best made with a planar, non-porous electrode.

In an attempt to remove porosity contributions from the electrochemical response a thin film of the insulating polymer poly(oxyphenylene) was electrochemically coated onto all electrochemically accessible areas of the BDD surface. The top surface of the polymer only, was then removed by a gentle polishing with micro alumina particles. Prior to coating with poly(oxyphenylene), the CV for 1 mM Ru(NH₃)₆³⁺ is as expected and shown in FIG. 5 (black line). When the insulating coating was applied, no electrochemical response is observed due to blocking of all accessible electron transfer sites. After gentle polishing of the top surface, the CV is now much better defined, smaller in current and significantly reduced in capacitive contributions. This is likely due to the coating filling the sub-surface pores and thus limiting the exposed BDD area to only the top surface of the compact. A peak to peak separation in 1 mM Ru(NH₃)₆³⁺ of 105 mV was determined.

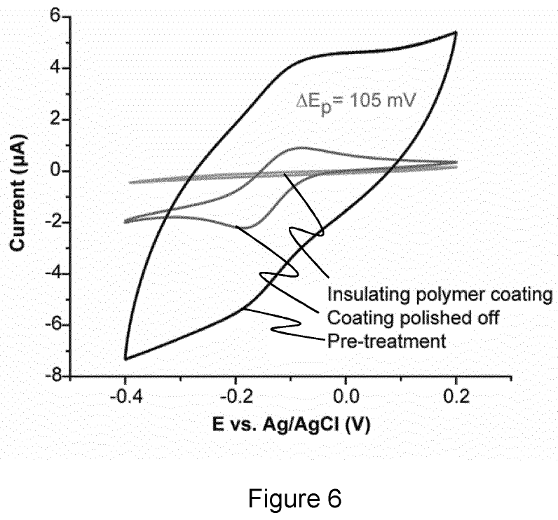

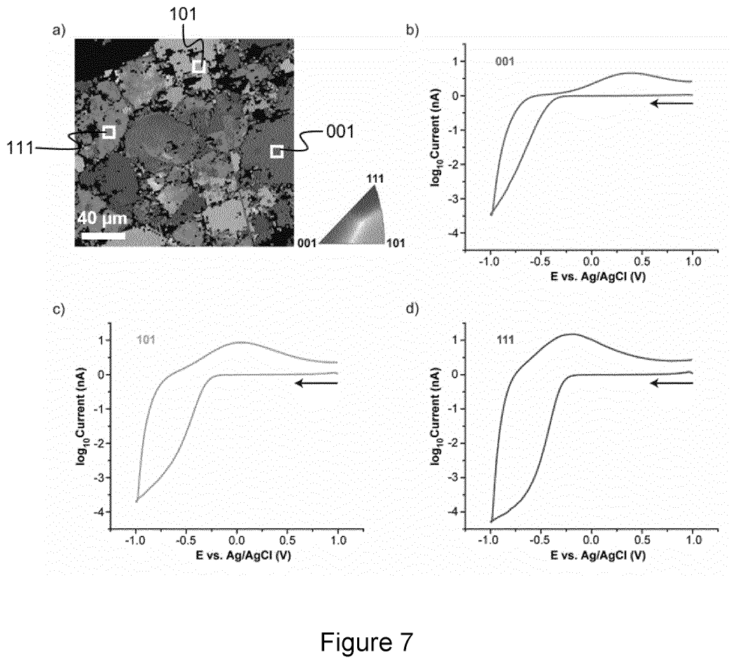

For higher resolution interrogation of the compact electrode, SECCM was carried out on a polymer free surface. FIG. 7a is an EBSD image of an SECCM scan area on the 4.8 wt % AlB₂ HPHT BDD compact. White squares indicate the locations from which the cyclic voltammograms shown in FIGS. 7b, 7c and 7d) were recorded. FIGS. 6b to 6d show typical cyclic voltammograms recorded in 10 mM Ru(NH₃)₆Cl₃ and 0.01 M KNO₃ at 10 V s⁻¹ on 001, 101, and 111 facets, respectively. Arrows indicate scan direction. All scans were performed in air.

EBSD demonstrates that the surface is composed of two types of regions as shown in FIG. 7a. The two types of region are well-defined crystal particles with randomly distributed different plane orientations, and areas where the plane orientation is poorly defined. The latter reflects the areas of crushed particles observed from FE-SEM images.

Cyclic voltammograms recorded for a 10 mM Ru(NH₃)₆³⁺ redox electrochemistry, with a ˜1 μm diameter SECCM tip electrode on three individual grains, 001, 101, 111, show a similar shape independent of surface structure (FIG. 6): at the start of the scan the current remains constant at around 0 nA before the current gradually decreases, starting from approximately 0 V to −0.3 V (called onset potential herein), then the current increases on the reverse scan with a peak occurring in the wide potential range of −0.2 V to +0.5 V. Variation in peak position and onset potential were found to be independent of crystallographic orientation.

Local capacitance values were estimated from equation 1, where iₐᵥ is the average current at 1 V from the forward and reverse sweep. The exposed geometric electrode area, A, during individual measurements was in the range of 2.5±0.2 μm measured from meniscus residues observed from FE-SEM secondary electron images. Capacitance values extracted were found to be 17±5 μF cm⁻², measured at the start of the SECCM scan. Maps of local capacitance as well as onset potential values did not reveal any specific pattern demonstrating homogeneous distribution across the surface around mean values.

The high current values observed by SECCM may be explained by the intrinsic sub-μm porosity of the HPHT BDD material. The shape of the cyclic voltammograms of FIGS. 7b to 7d indicate that dynamic diffusion of Ru(NH₃)₆³⁺ dominates as solution leaks into the surface as a result of porosity, which makes the response insensitive to the crystallographic surface structure and suggests that the degree of boron doping is similar in each region. As the scan area for each cyclic voltammogram is small, this suggests that not only do the HPHT BDD compacts have a porosity due to cracks between particles, but that the particle surfaces themselves may be porous, possibly due to the presence of crystallographic defects.

To remove particle-to-particle contact resistance contributions from the electrochemical behaviour, the electrochemical behaviour of a single BDD particle was interrogated.

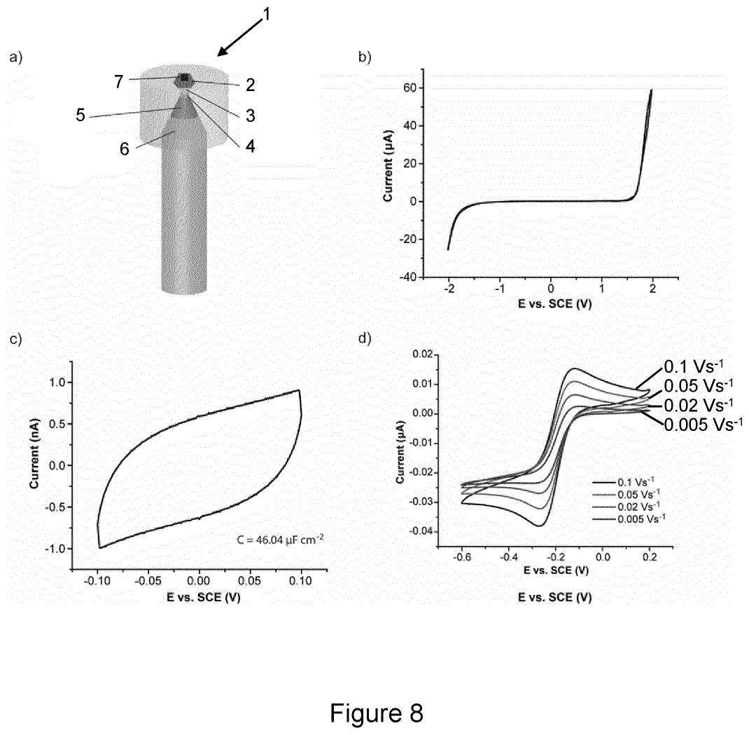

FIG. 8a illustrates schematically a structure of apparatus 1 for interrogating the electrochemical behaviour of a single BDD particle. A single BDD particle 2 is attached via a Ti/Au contact 3 and an Ag epoxy 4 to a copper wire 5 in an insulating casing 6. The BDD particle 2 is then encased in an epoxy resin 7, which is polished to expose a surface of the single BDD particle 2.

FIGS. 8b to 8d show cyclic voltammograms recorded in 0.1 M KNO₃ at a scan rate of 0.1 V s⁻¹ of the HPHT BDD SPE to show b) the solvent window, c) a typical capacitance curve recorded, and the electrode response in d) CVs recorded in 1 mM Ru(NH₃)₆^{3+/2+} and 0.1 M KNO₃ at scan rates of 0.1, 0.05, 0.02, and 0.005 V s⁻¹ for a HPHT BDD (4.8 wt % AlB₂ additive) SPE.

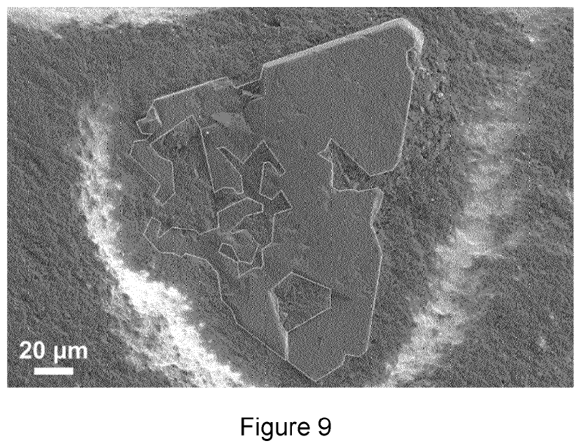

Studies were performed only on the 4.8 wt % AlB₂ particles because the Raman, GDMS and SIMS suggested the boron levels should be sufficient to achieve metal-like conductivity. FIG. 9 shows an FE-SEM image of the top surface of a silicon carbide polished HPHT BDD SPE, prepared as described above and shown in FIG. 8a. The white outline illustrates exposed BDD.

The exposed electrode area is irregularly shaped, approximately 1.3×10⁻⁴ cm² in geometric area, determined using ImageJ. From the capacitance scan, a value of 46 μF cm⁻² is determined, using equation 1. This may be an overestimation as the FE-SEM shows the BDD surface is not featureless and thus the geometric area underestimates the true electrochemically accessible area.

FIG. 8d shows the cyclic voltammograms for 1 mM Ru(NH₃)₆^{3+/2+} over the scan range 0.005 V s⁻¹ to 0.1 V s⁻¹. As the scan rate is reduced, the cyclic voltammogram changes shape from peak shaped to almost sigmoidal in response. This is indicative of, for the mass transport rates generated during the scan rate range applied, the electrode being on the limit of size for microelectrode behaviour. At the higher scan rates linear diffusion dominates, whilst at slower rates, a radial contribution is significant.

When the Tomeš criterion of reversibility (J. Tomeš, Collect. Czechoslov. Chem. Commun., 1937, 9, 12-21), which is commonly used to measure deviation from the theoretical 59 mV predicted for a one electron process at 25° C. by the Nernst equation, is applied to the CV recorded at a scan rate of 0.005 V s⁻¹ (FIG. 7), a value for E_{1/4}-E_{3/4} of 54 mV was obtained, suggesting that the particle is doped sufficiently with substitutional boron to display metallic conduction, although the surface porosity may be suppressing this value. Note that the cyclic voltammogram obtained does not quite represent a truly microelectrode response, owing to the electrode being slightly too large.

In summary, octahedral BDD particles were synthesised by a metal catalysed HPHT technique in an FeNi—B—C system at approximately 5.5 GPa and 1200° C. A high level of boron doping was achieved, estimated up to 2.94×10²⁰ atoms cm⁻³. Increasing the amount of AlB₂ additive in the growth mixture does result in slightly higher doping, this increase is not proportional. It is clear from this observation and FE-SEM imaging, where many crystallographic defects are recognised, that doping with boron hinders diamond growth.

Though a good electrochemical response was obtained for a single particle, the porosity of both the HPHT BDD particles themselves, and of the compact, results in an unusually high double layer capacitance. This unique property was confirmed through SECCM and polymer coating studies. The presence of this porosity does not however lessen the potential of this material, and in fact may be exploited for some applications, e.g. super-capacitors devices.

While this invention has been particularly shown and described with reference to preferred embodiments, it will be understood to those skilled in the art that various changes in form and detail may be made without departing from the scope of the invention as defined by the appendant claims. For example, while the examples above used AlB₂ as both a nitrogen getter and a source of boron, it will be appreciated that separate additions may be used to achieve add boron and remove nitrogen from the reaction mass. For example, the source of boron may be selected from amorphous boron, AlB₂, MgB₂ or other low melting point or low dissociation temperature borides, FeB, Mn₄B or other transition metal borides. The source of nitrogen getter material may be selected from Al, Ti, other elements of the (IUPAC) IVa group in the periodic table, and other chemical species that form stable N compounds.

It should further be noted that while the boron doped synthetic HPHT diamond materials of described above have been characterized in aqueous solution, it is envisaged that the materials may be used in other types of solution including organic solvents. As such, it will be understood that the characterisation of the materials is not intended to limit the use of the materials in a range of applications.

1. An electrode comprising synthetic high-pressure high-temperature diamond material, the synthetic high-pressure high-temperature diamond material comprising:
a substitutional boron concentration of between 1×10²⁰ and 5×10²¹ atoms/cm³;
a nitrogen concentration of no more than 10¹⁹ atoms/cm³; and
wherein the electrode has any of the following characteristics:
a ΔE_{3/4-1/4} as measured with respect to a saturated calomel reference electrode in an aqueous solution containing 0.1 M KNO₃ and 1 mM of Ru(NH₃)₆³⁺ selected any of less than 70 mV, less than 68 mV, less than 66 mV, and less than 64 mV; and
a peak to peak separation ΔEₚ as measured with respect to a saturated calomel reference electrode in an aqueous solution containing 0.1 M KNO₃ and 1 mM of Ru(NH₃)₆³⁺ selected any of less than 70 mV, less than 68 mV, less than 66 mV, and less than 64 mV.

2. The electrode according to claim 1, wherein an sp² carbon content of the electrode is sufficiently low as to not exhibit non-diamond carbon peaks in a Raman spectrum of the electrode.

3. The electrode according to claim 1, wherein the synthetic high-pressure high-temperature diamond material has a boron content selected from any one of at least 2×10²⁰ boron atoms cm⁻³, at least 3×10²⁰ boron atoms cm⁻³, at least 5×10²⁰ boron atoms cm⁻³, and at least 7×10²⁰ boron atoms cm⁻³.

4. The electrode according to any one of claim 1, comprising inter-grown grains of the synthetic high-pressure high-temperature diamond material.

5. The electrode according to any one of claim 1, comprising particles of the synthetic high-pressure high-temperature diamond material dispersed in or on an electrically non-conductive matrix material.

6. The electrode according to claim 5 wherein the non-conductive matrix material is selected from any of a polymer, Nafion, insulating oil, and an insulating ink.

7. The electrode according to any one of claim 1, comprising particles of the synthetic high-pressure high-temperature diamond material dispersed in or on a conductive matrix material.

8. The electrode according to claim 7 wherein the conductive matrix material is selected from any of a conducting polymer, a non-diamond carbon support, and conducting ink.

9. The electrode according to any one of claim 1, comprising a container containing particles of the synthetic high-pressure high-temperature diamond material, the container having at least one opening through which, in use, an electrolyte can pass.

10. The electrode according to claim 9, wherein the container comprises at least one wall, the wall having porosity through which, in use, the electrolyte can pass.

11. The electrode according to any one of claim 1, comprising a compacted body of particles of the synthetic high-pressure high-temperature diamond material.

12. The electrode according to claim 11, wherein the particles of synthetic diamond material have an average grain size selected from any of a range of 5 nm to 500 μm, 10 nm to 200 μm, 50 nm to 100 μm, and 100 nm to 10 μm.

13. A method of making an electrode comprising synthetic high-pressure high-temperature diamond material, the method comprising:
providing synthetic high-pressure high-temperature diamond material, the synthetic high-pressure high-temperature diamond material having a substitutional boron concentration of between 1×10²⁰ and 5×10²¹ atoms/cm³ and a nitrogen concentration of no more than 10¹⁹ atoms/cm³; and
forming the synthetic high-pressure high-temperature diamond material into an electrode.

14. The method according to claim 13, wherein the step of forming the synthetic high-pressure high-temperature diamond material into an electrode comprises providing a reaction mass comprising high-pressure high-temperature diamond material and a catalyst material;
subjecting the reaction mass to a temperature greater than 1300° C. and a pressure of greater than 4.0 GPa to form an body comprising inter-grown grains of diamond material; and
removing catalyst material from the body to form the electrode.

15. (canceled)

16. The method according to claim 13, wherein the step of forming the synthetic high-pressure high-temperature diamond material into an electrode comprises dispersing particles of the high-pressure high-temperature diamond material in or on an electrically non-conductive matrix material.

17. (canceled)

18. The method according to claim 13, wherein the step of forming the synthetic high-pressure high-temperature diamond material into an electrode comprises dispersing particles of the synthetic high-pressure high-temperature diamond material in or on a conductive matrix material.

19. (canceled)

20. The method according to claim 13, wherein the step of forming the synthetic high-pressure high-temperature diamond material into an electrode comprises providing a container having at least one opening and locating particles of the synthetic high-pressure high-temperature diamond material in the container.

21. The method according to claim 13, wherein the step of forming the synthetic high-pressure high-temperature diamond material into an electrode comprises compacting a plurality of particles of the synthetic high-pressure high-temperature diamond material at a pressure of at least 4.5 GPa and a temperature of at least 1400° C. to form a compacted body.

22. A particle of synthetic high-pressure high-temperature diamond material comprising:
a substitutional boron concentration of between 1×10²⁰ and 5×10²¹ atoms/cm³; and
a nitrogen concentration of no more than 10¹⁹ atoms/cm³; and
the particle of synthetic high-pressure high-temperature diamond material having any of the following characteristics:
a ΔE_{3/4-1/4} as measured with respect to a saturated calomel reference electrode in an aqueous solution containing 0.1 M KNO₃ and 1 mM of Ru(NH₃)₆³⁺ selected any of less than 70 mV, less than 68 mV, less than 66 mV, and less than 64 mV; and
a peak to peak separation ΔEₚ as measured with respect to a saturated calomel reference electrode in an aqueous solution containing 0.1 M KNO₃ and 1 mM of Ru(NH₃)₆³⁺ selected any of less than 70 mV, less than 68 mV, less than 66 mV, and less than 64 mV.

23. The particle of synthetic high-pressure high-temperature diamond material according to claim 22, having a substitutional boron content selected from any one of at least 2×10²⁰ boron atoms cm⁻³, at least 3×10²⁰ boron atoms cm⁻³, at least 5×10²⁰ boron atoms cm⁻³, and at least 7×10²⁰ boron atoms cm⁻³.

24. (canceled)
